(19) United States
(12) Patent Application Publication
(10) Pub. No.: US 2016/0064069 A1
(43) Pub. Date: Mar. 3, 2016

(54) LOW VOLTAGE SRAM

(71) Applicant: TEXAS INSTRUMENTS INCORPORATED, Dallas, TX (US)

(72) Inventors: Vinod MENEZES, Bangalore (IN); Premkumar SEETHARAMAN, Bangalore (IN)

(21) Appl. No.: 14/843,023

(22) Filed: Sep. 2, 2015

(30) Foreign Application Priority Data
Sep. 2, 2014 (IN) 4279/CHE/2014

(51) Int. Cl. G11C 11/419

(52) U.S. Cl. CPC G11C 11/419

(57) ABSTRACT

In some embodiments, an SRAM includes an array of storage cells arranged as rows and columns, each storage cell of the array of storage cells includes a first type of transistor and a second type of transistor. The SRAM also includes a memory controller configured to detect a temperature of the SRAM and apply a body bias to the first type of transistor in each of the storage cells and refrain from an application of a body bias to the second type of transistor in each of the storage cells.

### CROSS-REFERENCE TO RELATED APPLICATIONS

The present application claims priority to India Provisional Patent Application No. 4279/CHE/2014, filed Sep. 2, 2014, which is hereby incorporated herein by reference in its entirety.

### BACKGROUND

Static random access memory (SRAM) is memory that utilizes latching to store each bit. Because SRAM is static, there is no need to periodically refresh the memory; the transistors inside continue to hold the data as long as the power supply is not cut off. Although SRAM does not require additional circuitry and timing needed to periodically refresh the memory and thus it may consume less power than memory that needs periodic refreshing (i.e., dynamic random access memory (DRAM)), any reduction in power consumption of SRAM continues to be beneficial. Due to SRAM's speed, SRAM is typically used in computer applications that require a fast memory such as cache memory for the central processing unit (CPU), external burst mode SRAM caches, hard disk buffers, router buffers, CPU register files, etc.

Power consumption of SRAM may vary widely depending on how frequently the SRAM is accessed. Lower power consumption may be beneficial to SRAM that might be used in cache memory of processors, for example. Low power consumption may translate to less heat that needs to be dissipated. In addition, low power consumption is a desirable trait by designers trying to increase battery life for various portable devices such as smart phones, tablets and music players. Overall, reducing SRAM power consumption in any portable device that relies on high-performance system memory may benefit from solutions that reduce SRAM power consumption. Thus efforts continue to reduce power consumption of static random access memory (SRAM).

Various solutions exist regarding efforts to reduce the power consumption of SRAM including reducing the supply voltage to the SRAM. One drawback of reducing the supply voltage to SRAM is that the SRAM cell may behave erratically. It may be difficult to read or write to bit cells for example. In other instances, bit cells may be easily disturbed during a read or write on a different bit cell. Other consequences resulting from a lower supply voltage may be sluggish performance. For example, access times may increase, which defeats an advantage of SRAM which is typically fast access times.

### SUMMARY

The problems noted above are solved in part by systems and methods for increasing the robustness of a static random access memory (SRAM) during lower voltage conditions. In some embodiments, an SRAM includes an array of storage cells arranged as rows and columns, each storage cell of the array of storage cells includes a first type of transistor and a second type of transistor. The SRAM also includes a memory controller configured to detect a temperature of the SRAM and apply a body bias to the first type of transistor in each of the storage cells and refrain from an application of a body bias to the second type of transistor in each of the storage cells.

Another illustrative embodiment is an integrated circuit that include a processor and an SRAM coupled to the processor. The SRAM includes an array of storage cells arranged as row and columns. Each storage cell of the array of storage cells includes a first type of transistor and a second type of transistor. The SRAM also includes peripheral logic that includes a row decoder configured to select a row of storage cells, a column decoder configured to select a column of storage cells, and a sense amplifier configured to amplify a signal received from the storage cells. The integrated circuit also includes a memory controller configured to, for the storage cells, apply a forward body bias to a portion of the storage cells, where an amount of the forward body bias is based on a quality of the silicon of the SRAM.

In yet another illustrative embodiment, a method includes determining, by a memory controller coupled to an SRAM, a temperature of the SRAM, the SRAM including peripheral logic and an array of storage cells. The method additionally includes applying, based on a first temperature, a first amount of forward body bias to a first portion of a storage cell of the array without applying the first amount of forward body bias to a remaining portion of the storage cell. The method additionally includes applying, based on a second temperature, a second amount of forward body bias to the first portion of the storage cell without applying the second amount of forward body bias to the remaining portion of the storage cell, where the first amount of forward body bias and the second amount of forward body bias is based on a strength of a silicon of the SRAM.

### BRIEF DESCRIPTION OF THE DRAWINGS

For a detailed description of various examples, reference will now be made to the accompanying drawings in which:

FIG. 1 shows a block diagram of a computing system in accordance with various examples;

FIG. 2 shows a block diagram of a memory system in accordance with various examples;

FIG. 3 shows a circuit diagram of a memory storage cell in accordance with various examples;

FIG. 4 shows charts depicting various characteristics of an SRAM system in accordance with various examples;

FIG. 5 shows a flow diagram of a method of configuring an SRAM in accordance with various embodiments; and

FIG. 6 shows a flow diagram of a method of operating an SRAM in accordance with various embodiments.

### NOTATION AND NOMENCLATURE

Certain terms are used throughout the following description and claims to refer to particular system components. As one skilled in the art will appreciate, different companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . . ” Also, the term “couple” or “couples” is intended to mean either an indirect or direct wired or wireless connection. Thus, if a first device couples to a second device, that connection may be through a direct connection or through an indirect connection via other devices and connections.

Various units, circuits, or other components in this disclosure may be described or claimed as “configured to” perform a task or tasks. In such contexts, “configured to” is used to connote structure by indicating that the units/circuits/components include structure (e.g., circuitry) that performs those task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. §112(f) for that unit/circuit/component.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be an example of the embodiment, and not intended to intimate that the scope of the disclosure, including the claims, is limited to that embodiment.

Low power consumption may be beneficial to static random access memory (SRAM) that might be used in cache memory of processors. Additionally, reducing SRAM power consumption Overall, reducing SRAM power consumption in any portable device that relies on high-performance system memory may benefit from solutions that reduce SRAM power consumption.

Various solutions exist regarding efforts to reduce the power consumption of SRAM including reducing the supply voltage to the SRAM. One drawback of reducing the supply voltage to the SRAM is that the SRAM cell may behave erratically. An approach including applying selective forward body bias to only a portion of the transistors in the SRAM data array may result in a storage cells that remain robust and experience improved stability despite being subject to a reduced supply voltage. The approach may also result in read and write assists occurring during read and write operations to the storage cells.

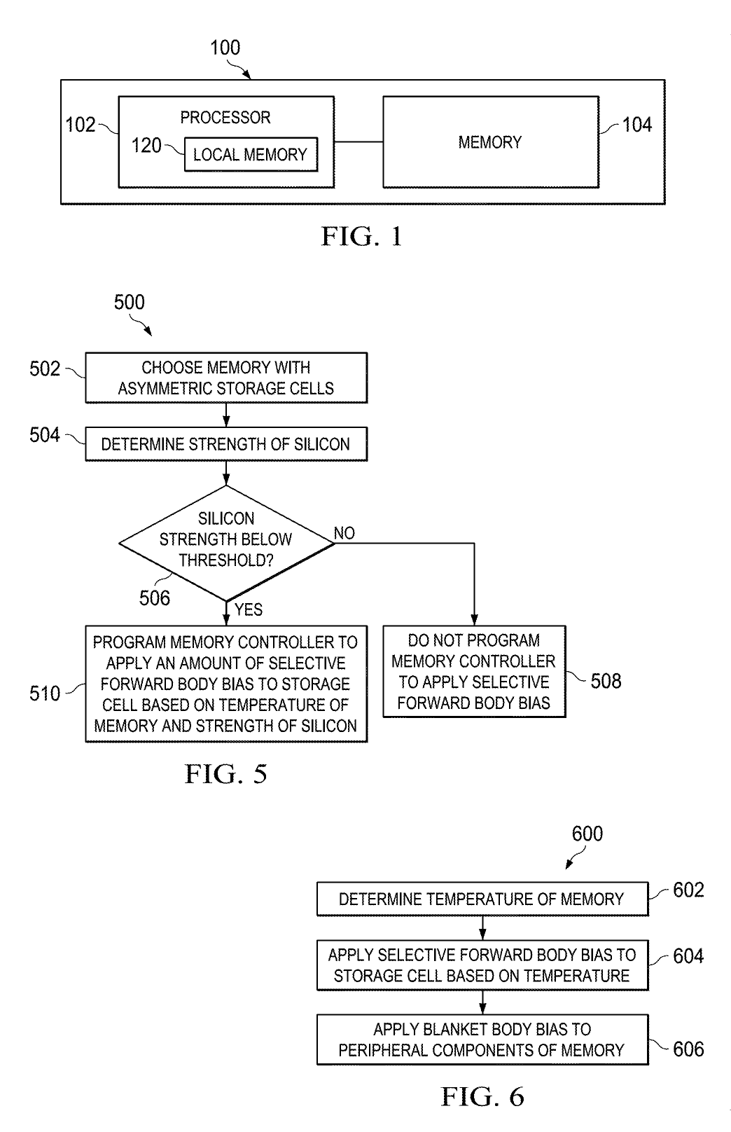

FIG. 1 shows a computer system 100 which may be illustrative of a computing system, system on a chip, integrated circuit, or other system implementing embodiments of a memory as disclosed below. Computing system 100 comprises processor 102 and memory 104. Computing system 100 may also include various additional components, such as a transceiver, clock generators, input/output ports, analog-to-digital and digital-to-analog conversion chips, radio frequency (RF) amplifiers, and additional storage devices. The computing system 100 may be illustrative of various devices such as a laptop, tablet, gaming system, television, mp3 player, or any other computing device that utilizes SRAM or other memory systems that may benefit from the disclosure below.

In various embodiments, although depicted as processor 102, processor 102 may comprise more than one processor. Processor 102 may comprise a microprocessor, a digital signal processor, a microcontroller, a central processing unit (CPU), a graphics processing unit (GPU), or both a CPU and GPU, or other suitable device configured to execute instructions for performing operations. Processor architectures generally include execution units (e.g., fixed point, floating point, integer, etc.), instruction decoding, peripherals (e.g., interrupt controllers, timers, direct memory access controllers, etc.), input/output systems (e.g., serial ports, parallel ports, etc.) and various other components and sub-systems.

Additionally, the processor 102 may include a local memory 120 that may store program modules, program data, and/or portions of one or more operating systems. In various embodiments, the local memory 120 may include a cache memory comprising SRAM. In several embodiments, SRAM is a static random access memory which may provide storage of data and/or instruction that are capable of being processed by processor 102. As is known in the art, SRAM is comprised of an array of bit cells where each bit cell utilizes latching circuitry to store a bit of data.

Programs executable by the processor 102 may be stored on the memory 104 or alternatively, the programs may be stored on a different storage device within computing system 100 (e.g., a hard drive, solid state disk, memory stick, optical disc), and accessed when needed by the processor 102. The program stored in memory 104 may comprise programs to implement various processes on the computing system 100. The memory 104 may comprise dynamic random access memory (DRAM) or SRAM.

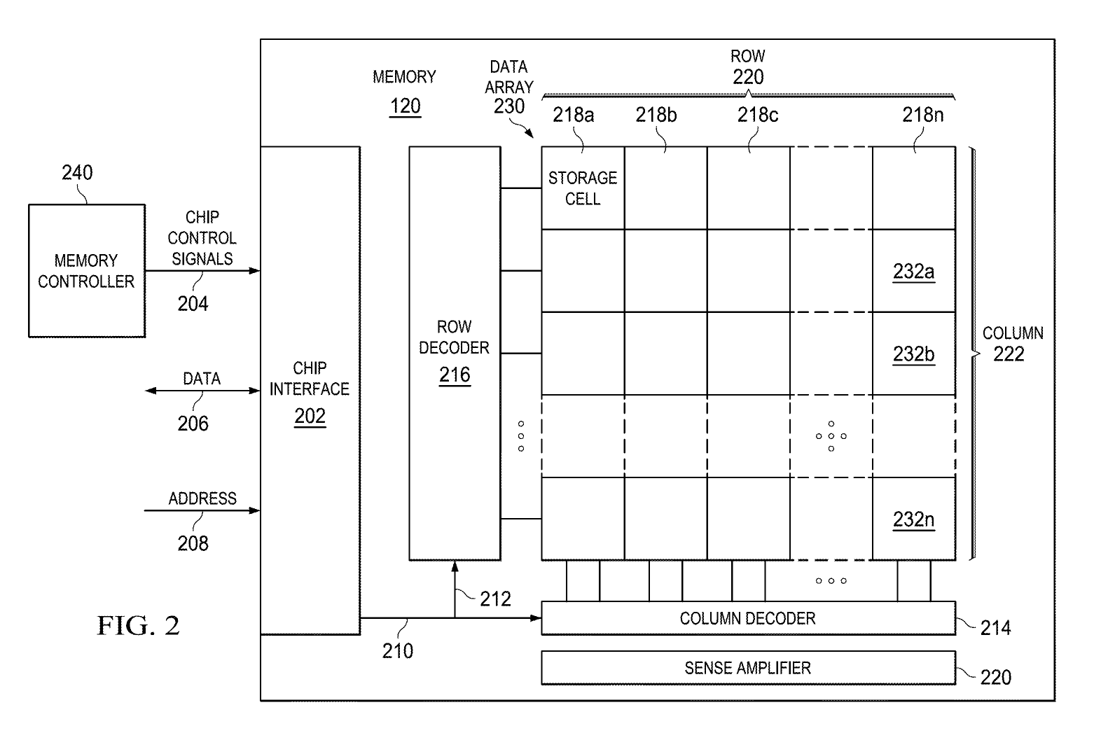

FIG. 2 shows a block diagram of memory 120 in which memory 120 comprises SRAM. In various embodiments, memory 120 comprises a chip interface 202. As depicted, chip interface 202 may receive chip control signals 204 from a memory controller 240. In various embodiments, as discussed below, the memory controller 240 may be configured to detect a temperature of the memory 120 and apply a selective forward body bias on a portion of the transistors in each storage cell in the data array 230.

Memory controller 240 may be configured to apply different amounts of a selective forward body bias based on a detected temperature of the memory 120. In various embodiments, the amount of selective forward body bias applied to a portion of each storage cell in data array 230 may also be based on a strength of the silicon. As discussed further below, memory controller 240 may be configured to apply a selective forward body bias to only one type of transistor in each storage cell of data array 230.

Chip interface 202 may also receive data 206 and address data 208. Data 206 may flow between memory 120 and a processor, such as processor 102 through chip interface 202. Data 206 may comprises data sent to and from memory 120 during read and write operations of the memory 102. Address 208 may comprise signals 210 and 212 that are decoded by row decoder 216 and column decoder 214.

As depicted, memory 120 comprises a data array 230 in accordance with various embodiments. Data array 230 may be arranged as rows and columns of storage cells, sometimes referred to as bit cells. For example, as depicted, data array 230 comprises a row 220 of storage cells 218a, 218b, 218c, . . . , 218n. Row 220 may be selected by row decoder 216, based on a signal 212 received by row decoder 216. Similarly, column 222 comprises storage cells 218n, 232a, 232b, . . . , 232m. Column 222 of the data array 230 may be selected by column decoder 214 based on a signal 210 received by column decoder 214. Thus, row and column selection operations are accomplished by row decoder 216 and column decoder 214.

In various embodiments, memory 120 may comprise sense amplifier 220. As discussed below, a storage cell, such as storage cell 218a may produce a differential voltage that may be detected on two bit lines of a storage cell 218a. Sense amplifier may receive the differential voltage as an input and amplify the signal such that it may be properly interpreted as a stored “0” or “1” in the storage cell 218a.

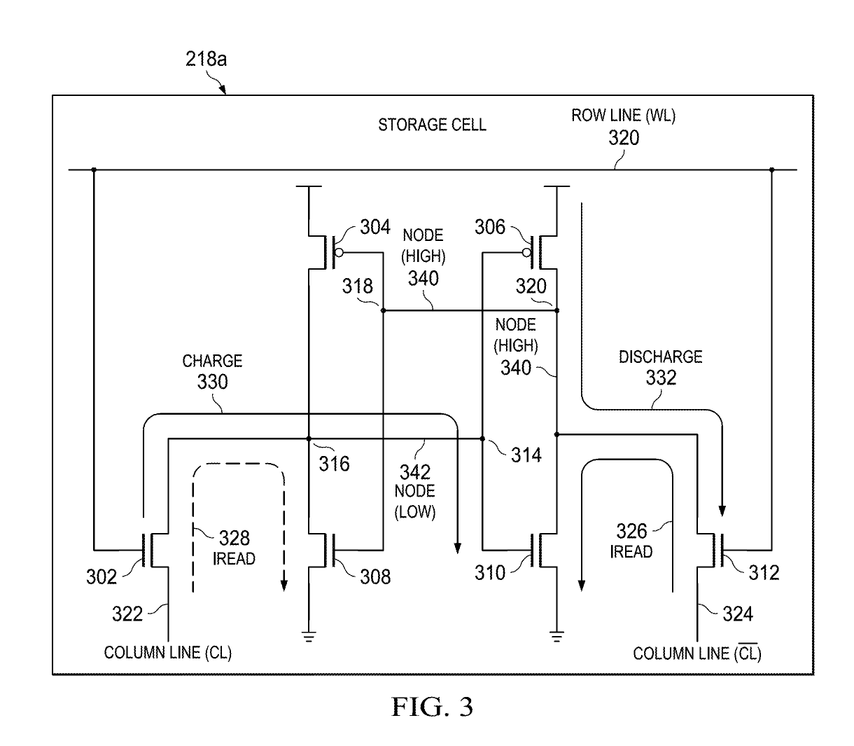

FIG. 3 shows a circuit diagram of storage cell 218a. In various embodiments, storage cell 218a represents a six transistor (6T) SRAM bit cell. As depicted storage cell 218a comprises six transistors 302, 304, 306, 308, 310, and 312. As depicted, transistors 304 and 306 comprise p-type metal-oxide semiconductor (pMOS) transistors and the remaining transistors 302, 308, 310, and 312 comprise n-type metal-oxide semiconductor (nMOS) transistors. In turn, pMOS transistor 304 and nMOS transistor 308 form an inverter. Similarly, pMOS transistor 306 and nMOS transistor 310 form an inverter. As depicted through node connections 314 and 318, the output of one inverter 314 or 318 is tied to the respective input of the other inverter (i.e., connections 314 and 318 are tied respectively to connections 316 and 320). Thus the inverters are cross-coupled.

In various embodiments, row line 320 may be used to select the storage cell 218a during a read or write operation. In the embodiment where storage cell 218a is a 6T SRAM bit cell, row line 320 may be similar to a word line.

As depicted, in various embodiments nMOS transistors 302 and 312 may be referred to as pass gates, through which data may be written to or read out of the storage cell 218a. For example, during a read operation, column lines 322 and 324 may be initially charged to a certain value. Upon selection of the storage cell 218a through row line 320, the nMOS transistors 302 and 312 may be turned to an on state. Depending on whether a “0” or a “1” is stored in the storage cell 218a, a current Iread 326 may flow through nMOS transistors 312 and 310 such that column line 324 is pulled to ground. Alternatively, a current Iread 328 may flow through nMOS transistors 302 and 308 such that column line 322 is pulled to ground. During the read operation, only one column line 322 or 324 will begin to discharge. Thus during a read operation nMOS transistors 310 and 312 or nMOS transistors 302 and 308 act as if tied in series. A discharge through nMOS transistors 310 and 312 or nMOS transistors 302 and 308 will result in a slight decrease in the voltage on either column line 322 or 324.

Continuing the discussion of FIG. 3, the resulting difference in voltage between column line 322 and 324 may be referred to as a differential voltage. The differential voltage may indicate whether a “1” or a “0” is stored within storage cell 218a. In several embodiments, the differential voltage that is produced comprises a tiny amount of voltage. Accordingly, the differential voltage may be transferred to a sense amplifier which amplifies the signal after which the signal may be interpreted as a “1” or a “0.” In various embodiments, a memory 120 may be configured to wait until a threshold amount of differential voltage is detected before the differential voltage is transferred to a sense amplifier.

In various embodiments, storage cell 218a may be an asymmetric bit cell such that some of the transistors 302, 304, 306, 308, 310, and 312 are fabricated or operated in a manner such that some of the transistors 302, 304, 306, 308, 310, and 312 are of different strengths. In various embodiments, the pMOS and nMOS transistors 302, 304, 306, 308, and 310 may be strategically sized (i.e., different width and length of the transistors) or fabricated or operated such that the transistors 302, 304, 306, 308, 310, and 312 have different threshold voltages. Thus, different transistors may require different voltages before the transistor transitions from an off state to one in which it conducts current and vice versa. In various embodiments, the storage cell 218a may be fabricated or operated to be asymmetric such that a static noise margin of the storage cell 218a is fairly high.

In various embodiments, storage cell 218a, having a high static noise margin, may result in the storage cell 218a being one that is difficult to write to; and thus, it may be deemed to have a poor write margin. However, with a high static noise margin, bits stored within storage cells of the data array 230 will not be disturbed easily. In various scenarios, the value of a static noise margin of a storage cell may be based on a measure of how easily a bit cell may flip in the process of a read operation.

As mentioned previously, one solution to reduce power consumption in SRAM has been to reduce the supply voltage to the SRAM. Lowering the supply voltage may reduce leakage power and dynamic power. The supply voltage to the SRAM may be reduced up to a certain point before certain drawbacks start to occur. For example, with a lower supply voltage a designer may risk trading lower power consumption for reduced performance, increased instability, or potentially a storage cell that may not properly be read or written to.

In some scenarios, a reduced supply voltage results in a reduced voltage to the structure of the memory which in turn results in a drop in the read current during a read operation, for example. With a reduction in read current, the amount of time before a differential voltage reaches a threshold amount increases. Thus, the access times for the SRAM increases which results in a performance drop. Additionally, with a reduced supply voltage, bit cells may be disturbed during read and write operations. During a read or write operation to a first cell, bits may flip in adjacent or surrounding cells.

Continuing the discussion of FIG. 3, as disclosed herein, an approach comprising applying selective forward body bias to only a portion of the transistors in the storage cell 218a may result in a storage cell that remains robust and experiences improved stability despite being subject to a reduced supply voltage. In various embodiments, a forward body bias is applied to one type of transistor within the storage cell 218a. For example, a forward body bias may be applied to the nMOS transistors 302, 308, 310, and 312 only, which no forward body bias is applied to the pMOS transistors 304 and 306.

In this example, as discussed further below, a read assist, a write assist, and a reduced static noise margin may result. By applying a forward body bias to the nMOS transistors 302, 308, 310, and 312 only (and not applying a forward bias to the pMOS transistors 304 and 306) the threshold voltage for these transistors 302, 308, 310, and 312 is reduced. As discussed previously, the nMOS transistors 302, 308, 310, and 312 may be involved in the read operation when an Iread current 326 or 328 passes through the respective nMOS transistors 310 and 312 or 302 and 308. As a result of a reduced threshold voltage of the nMOS transistors 302, 308, 310, and 312, a read assist may occur. This is due to the fact that with a reduced threshold voltage, the nMOS transistors (i.e., either nMOS transistors 302 and 308 or nMOS transistors 310 and 312) involved during a read operation will begin discharging with a lower voltage applied at the gates of the nMOS transistors 302, 308, 310, and 312 than would be required otherwise in a scenario where a forward body bias in not applied to the nMOS transistors 302, 308, 310, and 312.

Stated another way, in an example where nMOS transistors 310 and 312 discharge the column line 324 during a read operation, with a forward body bias applied to the nMOS transistors 310 and 312, a first voltage applied at the gates will result in an increased amount of Iread current 326 than would result if the same first voltage were applied at the gates but without the application of the forward body bias on these nMOS transistors 310 and 312.

With an increase in Iread current 326 occurring with the selective application of the forward body bias on only the nMOS transistors 302, 308, 310, and 312, faster access times may occur than if the forward body bias was not applied to the nMOS transistors 302, 308, 310, and 312. With an increased Iread current 326, a differential voltage of the column lines 322 and 324 may reach a threshold amount, sufficient to send to the sense amplifier 220, faster. Accordingly, with a forward body bias applied to the transistors 302, 308, 310, and 312, an application of the first voltage level may result in increased Iread current, which may result in a faster access time than if the first voltage amount were applied without the application of the selective forward body bias. Accordingly, a read assist results from the selective application of the forward body bias on only the nMOS transistors 302, 308, 310, and 312.

As explained below, with the application of a forward body bias on only the nMOS transistors 302, 308, 310, and 312 in the storage cell 218a, a write assist may also occur. In various embodiments, storage cell 218a may benefit from a strong nMOS 302 or 312 due to the application of forward body bias to these transistors. In various embodiments, due to the boost in strength of either the nMOS 302 or 312, the nMOS 302 or 312 may more easily flip the bit of the nMOS 302 or 312 as the transistors are likely to be able to overcome a pMOS 304 or 306 more easily than if a forward body bias was not applied to only the nMOS transistors 302, 308, 310, and 312.

Continuing the discussion of FIG. 3, as discussed previously, in several embodiments, storage cell 218a is an asymmetric storage cell in which a write operation is difficult to implement. By forward biasing only the nMOS transistors 302, 308, 320, and 312, the static noise margin of the asymmetric storage cell is reduced, however, a write operation is easier to complete due to the write assist produced by the forward body bias.

In one example, during a write operation, one of column lines 322 and 324 may be pulled high while the other is pulled low. In an additional example where the storage cell 218a stores a “0,” a node 340 may be at a level corresponding to high level and a node 342 may be at level corresponding to a low level. In this example, when an attempt is made to write a “1” to the storage cell, column line 322 may be pulled high and column line 324 may be pulled low. Additionally, nMOS 302 may drive node 342 to a high level and effectively flip the bit. With a reduced threshold voltage of nMOS transistor 302, due to a forward body bias applied to nMOS transistor 302, a charge 330 may effectively be driven on node 342 through nMOS transistor 302.

Additionally, during a write operation, a write driver may pull charge out of the storage cell 218a, depicted as discharge 332. Charge from a supply of the pMOS transistor 306 may discharge through a path consisting of the pMOS transistor 306, the nMOS transistor 312, and ground. With a reduced threshold voltage of nMOS transistor 312, due to the forward body bias applied to the nMOS transistor 312, the write driver may be able to draw more current out of the storage cell than it would be able to if no forward body bias was applied to nMOS transistor 312.

Accordingly, applying a forward body bias to only the nMOS transistors 302, 308, 310, and 312 and not the pMOS transistors 304 and 306 may be beneficial to operating a storage cell 218a with a low supply voltage. Although the application of the forward body bias on the nMOS transistors 302, 308, 310, and 312 may result in reducing the static noise margin of the storage cell 218a, as discussed above, storage cell 218a is an asymmetric cell which initially has a strong static noise margin. The reduction in static noise margin that results from applying the forward body bias to nMOS transistors 302, 308, 310, and 312 is does not degrade the performance of the storage cell 218a to a level that is significant. The application of the selective forward body bias results in a read assist and a write assist that enables the storage cell 218a to operate in a robust manner while also improving the performance of the bit cell despite having a reduced supply voltage. In various embodiments, applying a selective forward body bias as discussed may also help reduce latch-up issues.

Turning back to FIG. 2, in various embodiments, a blanket forward body bias may be applied to the peripheral components of memory 120, including the row decoder 216, column decoder 214. Peripheral components of memory 120 include components other than the storage cells in data array 230. In various embodiments, unlike the selective forward body bias applied to one type of transistor within storage cell 218a, the blanket forward body bias may be applied to both types of transistors (i.e., nMOS and pMOS transistors) within the peripheral components of the memory 120.

Returning to FIG. 3, the application of the forward body bias to the only the nMOS transistors 302, 308, 310, and 312 in the storage cell 218a, discussed above, may be beneficial in various embodiments where silicon is weak or the storage cell 218a is operating at lower temperatures. In various examples, silicon may be considered to be weak when transistors in the silicon demonstrate slow response times, or leakage is high within the transistors.

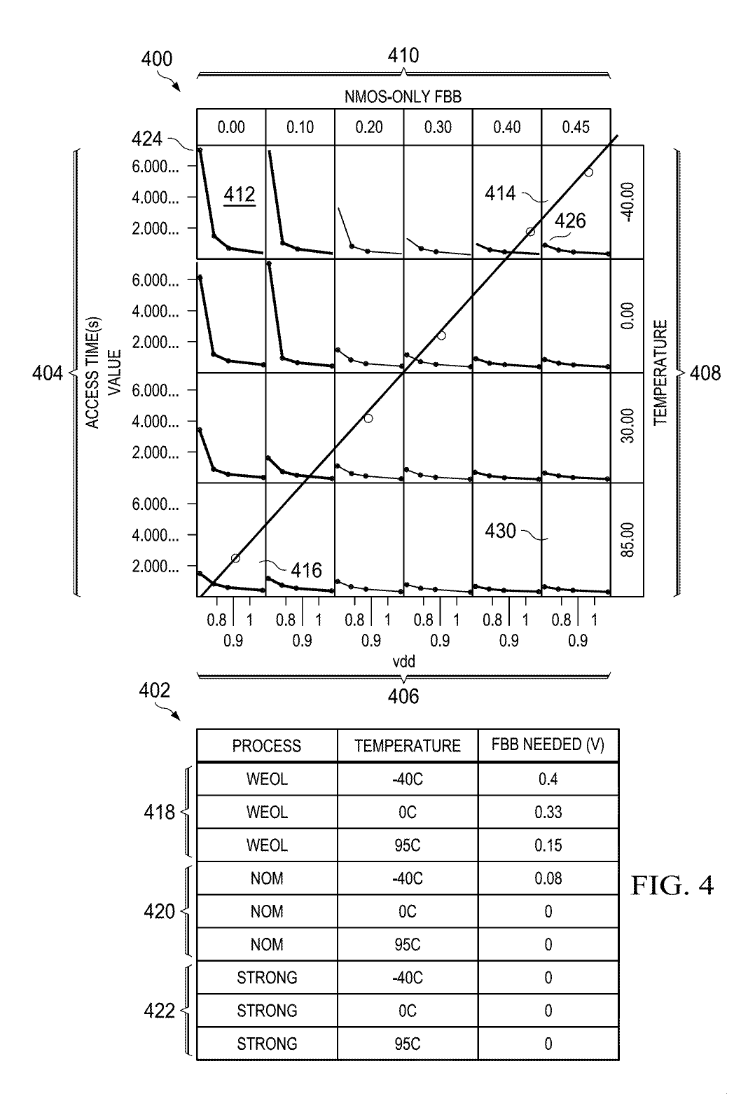

Turning now to FIG. 4, charts 400 and 402 depicting various characteristics of an SRAM system in which selective forward body bias is applied only to the nMOS transistors in each bit cell, are shown. Chart 400 depicts 4 rows and 6 columns which create individuals charts of data. In chart 400, an axis 404 represents access times of an SRAM bit cell with selective forward body bias applied. Axis 406 represents a supply voltage of the SRAM. Axis 408 represents temperature values. And axis 410 represent an amount of forward body bias applied to nMOS transistors in a bit cell.

As can be seen, a selective forward body bias may be beneficial when applied to silicon that is weak or an SRAM operating in colder temperatures. For example, as can be seen in cell 412, point 424 represents a scenario in which zero forward body bias is applied to the nMOS transistors in an SRAM that has a fairly long access time at a lower supply voltage (i.e., longer than 6 seconds). The access time is reduced for the silicon represented in cell 412 with the increase of the supply voltage.

As can be seen in cell 414, point 426, with the application of a maximum amount of selective forward body bias depicted in this chart, the access times for the SRAM at a lower supply voltage is significantly decreased (i.e., less than 2 seconds). Thus, in scenarios where silicon may be weak, the application of the forward body bias may be beneficial to the performance of the SRAM, especially when it is desirable to operate weak silicon with a lower supply voltage. Additionally, as can be seen in cell 414, the beneficial impact that applying the forward body bias to the silicon may also be a factor of the temperature of the SRAM. As depicted in cells 412 and 414, the SRAM is operating at a temperature of negative 40 degrees Celsius.

At the bottom left corner of chart 400 at cell 416, a different case is shown. In cell 416, as depicted the silicon appears to be fairly strong. An access time is less than 2 seconds for the SRAM bit cell under conditions where no selective forward body bias is applied and a low supply voltage is applied to the bit cell. As depicted in cell 430, an application of the maximum amount of selective forward body bias does improve the access time in a case where a low supply voltage is applied to the bit cell. However, this slight increase in access time may be outweighed by concerns of increasing instability of the SRAM. This instability may caused due to an increased amount of leakage current which in turn may be due to the forward bias applied to the nMOS transistors in the bit cell. Additionally, as can be seen in cells 416 and 430, this data correlates to the SRAM cell operating under hot conditions (i.e., 85 degrees Celsius).

Thus in various embodiments, after fabrication of an SRAM memory, an analysis may be conducted corresponding to the strength of the silicon. Subsequently a memory controller may be programmed to apply certain amounts of selective forward body bias to bit cells in the SRAM based on a strength of the silicon and temperature of the SRAM. If the silicon is considered to be strong, a memory controller may be programmed to not apply a selective forward body bias to the nMOS transistors in the SRAM bit cells. If the silicon is assessed to be weak, a memory controller may be programmed to apply selective forward.

Chart 402 depicts various suggested values for an application of selective forward bias. Group 418 corresponds to weak end of life silicon. According to chart 402, different selective forward bias values may be applied to weak end of life silicon based on a temperature of the silicon. Group 420 corresponds to nominal silicon and group 422 corresponds to strong silicon. As can be seen in chart 402, for strong silicon, no selective forward body bias may be applied. For nominal silicon, a small amount of selective forward body bias may be applied when the silicon is operating in cold temperature (i.e., negative 40 degrees Celsius)

Turning now to FIG. 5, a flow diagram 500 of a method of configuring an SRAM in accordance with various embodiments is shown. In various embodiments, some of the blocks shown in FIG. 5 may be performed concurrently, in a different order than shown, or omitted. Additional method elements may be performed as desired.

At block 502, a memory is chosen with asymmetric storage cells. As discussed previously, an asymmetric storage cell may be chosen such that initially, it has a strong static noise margin. At block 504, a strength of the silicon may be determined. The silicon may be assessed to determine a speed of transistors in the silicon or an amount of leakage current present during operation of the transistors.

At decision block 506, a determination is made as to whether an assessed silicon strength is below a threshold. This determination may determine whether silicon is weak, nominal, or strong. If silicon is assessed to be strong, i.e., above the threshold, then flow proceeds to block 508 at which a memory controller of the SRAM is programmed to not apply selective forward body bias to the storage cells.

If silicon is assessed to be below a threshold, i.e., nominal or weak, then flow proceeds to block 510. At block 510, a memory controller may be programmed to apply an amount of selective forward body bias to a storage cell based on the temperature of the memory and the strength of the silicon.

Turning now to FIG. 6, a flow diagram 600 of a method of applying selective forward body bias in an SRAM storage cell in accordance with various embodiments is shown. In various embodiments, some of the blocks shown in FIG. 6 may be performed concurrently, in a different order than shown, or omitted. Additional method elements may be performed as desired.

At block 602, a memory controller of an SRAM may determine a temperature of the memory. At block 604, the memory controller may apply selective forward body bias to storage cells of the SRAM based on the determined temperature. As discussed previously, the memory controller may be programmed with the information regarding how much selective forward body bias to apply for a certain temperature. At block 606, the memory controller may additionally apply a blanket body bias to peripheral components of the SRAM.

From the description provided herein, those skilled in the art are readily able to combine software with appropriate general-purpose or special-purpose computer hardware to create a computer system and/or computer sub-components in accordance with the various embodiments.

References to “one embodiments,” “an embodiment,” “some embodiments,” “various embodiments,” or the like indicate that a particular element or characteristic is included in at least one embodiment of the invention. Although the phrases may appear in various places, the phrases do not necessarily refer to the same embodiment.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A static random access memory (SRAM) comprising:
an array of storage cells arranged as rows and columns, each storage cell of the array of storage cells comprising a first type of transistor and a second type of transistor; and
a memory controller configured to:
detect a temperature of the SRAM; and
apply a body bias to the first type of transistor in each of the storage cells and refrain from an application of a body bias to the second type of transistor in each of the storage cells.

2. The SRAM of claim 1, wherein:
the first type of transistor is an n-type metal-oxide semiconductor (nMOS) transistor;
the second type of transistor is a p-type metal-oxide semiconductor (pMOS) transistor; and
the array of storage cells comprises six transistor (6T) SRAM cells.

3. The SRAM of claim 1, wherein the memory controller is further configured to apply an amount of body bias to the first type of transistor based on a temperature of the SRAM.

4. The SRAM of claim 1, wherein:
the array comprises asymmetric storage cells; and
the asymmetric storage cells comprise a first transistor comprising a threshold voltage with a first value and a second transistor comprising a threshold voltage with a second value different from the first value.

5. The SRAM of claim 1, wherein:
the memory controller is further configured to apply a forward body bias to the first type of transistor; and
the first type of transistor is an n-type metal-oxide semiconductor (nMOS) transistor.

6. The SRAM of claim 1 further comprises:
logic that includes a row decoder configured to select a row of storage cells, a column decoder configured to select a column of storage cells, and a sense amplifier,
wherein the logic comprises n-type metal-oxide semiconductor (nMOS) transistors and p-type metal-oxide semiconductor (pMOS) transistors; and
wherein the memory controller is further configured to apply a forward body bias to the nMOS transistors and pMOS transistors of the logic.

7. The SRAM of claim 1, wherein the memory controller is further configured to apply an amount of body bias based on a quality of silicon of the SRAM, wherein the quality of the silicon is based on at least one of: a speed of transistors on the silicon and an amount of leakage current of the transistors.

8. The SRAM of claim 7, wherein:
the memory controller is further configured to:
detect a temperature of the SRAM;
compare the temperate to a predetermined threshold;
apply a first amount of forward body bias to the first type of transistor in response to a determination that the temperature is below the predetermined threshold; and
apply a second amount of forward body bias to the first type of transistor in response to a determination that the temperature is above the predetermined threshold;
the predetermined threshold is based on the quality of the silicon of the SRAM.

9. The SRAM of claim 1, wherein:
the first type of transistor comprises an n-type metal-oxide semiconductor (nMOS) transistor;
for each of the storage cells, the memory controller is further configured to apply a forward body bias to a plurality of nMOS transistors of the storage cell such that a second static noise margin of the storage cell is less than a first static noise margin of the storage cell;
the first static noise margin of the storage cell corresponds to a static noise margin of the storage cell without an application of a forward body bias on the plurality of nMOS transistors; and
the second static noise margin of the storage cell corresponds to a static noise margin of the storage cell with an application of a forward body bias on the plurality of nMOS transistors.

10. An integrated system comprising:
a processor; and
a static random access memory (SRAM) coupled to the processor, the SRAM comprising:
an array of storage cells arranged as rows and columns, each storage cell of the array of storage cells comprising a first type of transistor and a second type of transistor;
a peripheral logic comprising:
a row decoder configured to select a row of storage cells;
a column decoder configured to select a column of storage cells;
a sense amplifier configured to amplify a signal received from the storage cells; and
a memory controller configured to, for the storage cells:
apply a forward body bias to a portion of the storage cell, an amount of the forward body bias based on a quality of a silicon of the SRAM.

11. The integrated system of claim 10, wherein:
the first type of transistor comprises an n-type metal-oxide semiconductor (nMOS) transistor;
the second type of transistor comprises a p-type metal-oxide semiconductor (pMOS) transistor; and
the array of storage cells comprises six transistor (6T) SRAM cells.

12. The integrated system of claim 11, wherein:
the memory controller is further configured to apply the amount of forward body bias based on a temperature of the SRAM and apply the forward bias to the plurality of nMOS transistors without applying the forward bias to the pMOS transistors.

13. The integrated system of claim 11, wherein the quality of the silicon is based on at least one of: a speed of the SRAM during operation and an amount of leakage current of the SRAM during operation.

14. The integrated system of claim 10, wherein one of the storage cells is an asymmetric storage cell, the asymmetric storage cell comprising a first transistor having a threshold voltage with a first value and a second transistor having a threshold voltage with a second value, the second value different from the first value.

15. The integrated system of claim 10, wherein:
the memory controller is further configured to apply forward body bias to the nMOS transistors such that a second amount of current associated with a read operation is greater than a first amount of current associated with the read operation,
the first amount of current corresponding to the SRAM without an application of the forward body bias to a portion of the storage cell, the first amount of current corresponding to an application of a first amount of voltage applied to a bit line of the storage cell during the read operation, and
the second amount of current corresponding to the SRAM with an application of the forward body bias to a portion of the storage cell, the second amount of current corresponding to an application of the first amount of voltage applied to the bit line of the storage cell during the read operation.

16. The integrated system of claim 10, wherein:
the first type of transistor comprises an n-type metal-oxide semiconductor (nMOS) transistor;
the second type of transistor comprises a p-type metal-oxide semiconductor (pMOS) transistor; and
the memory controller is further configured to:
compare a temperature of the SRAM to a predetermined threshold;
apply a first amount of forward body bias to the nMOS transistors in response to a determination that the temperature is below the predetermined threshold; and
apply a second amount of forward body bias to the nMOS transistors in response to a determination that the temperature is above the predetermined threshold.

17. A method comprising:
determining, by a memory controller coupled to a static random access memory (SRAM), a temperature of the SRAM, the SRAM comprising peripheral logic and an array of storage cells;
applying, based on a first temperature, a first amount of forward body bias to a first portion of a storage cell of the array without applying the first amount of forward body bias to a remaining portion of the storage cell; and
applying, based on a second temperature, a second amount of forward body bias to the first portion of the storage cell without applying the second amount of forward body bias to the remaining portion of the storage cell;
wherein the first amount of forward body bias and the second amount of forward body bias is based on a strength of a silicon of the SRAM.

18. The method of claim 17, wherein:
the array of storage cells comprises an asymmetric bit cell that includes a first transistor with a first threshold voltage and a second transistor with a second threshold voltage, the second threshold voltage different from the first threshold voltage;
the strength of the silicon is based at least in part on one of: a speed of the SRAM during operation and an amount of leakage current of the SRAM during operation; and
each of the storage cells in the array is a six transistor (6T) SRAM cell, the 6T SRAM cell including a plurality of n-type metal-oxide semiconductor (nMOS) transistors and a plurality of p-type metal-oxide semiconductor (pMOS) transistors.

19. The method of claim 18, wherein the applying the first amount of forward body bias and the second amount of forward body bias to the first portion of the storage cell further comprises:
applying a forward body bias to the plurality of nMOS transistors of the 6T SRAM cell without applying a forward body bias to the pMOS transistors of the 6T SRAM cell.

20. The method of claim 17, further comprising:
applying a forward body bias to a plurality of n-type metal-oxide semiconductor (nMOS) transistors of the peripheral logic and a plurality of p-type metal-oxide semiconductor (pMOS) transistors of the peripheral logic.
